(19) United States
(12) Patent Application Publication
(10) Pub. No.: US 2005/0110040 A1
(43) Pub. Date: May 26, 2005

(54) TEXTURE FOR LOCALIZING AND MINIMIZING EFFECTS OF LATTICE CONSTANTS MISMATCH

(76) Inventor: Hui Peng, Fremont, CA (US)

Correspondence Address: Hui Peng, 35964 Vivian Place, Fremont, CA, 94536, US

(21) Appl. No.: 10/723,046

(22) Filed: Nov. 26, 2003

(51) Int. Cl. H01L 31/0328

(52) U.S. Cl. 257/190

(57) ABSTRACT

Lattice mismatch is a critical issue for semiconductor devices including nitride LED. Texturing a substrate, texturing an epitaxial layer, and a method are disclosed in the present invention for localizing and minimizing the effects of lattice mismatch. Texturing may be applied for more than once on the same epitaxial wafer. Thus different epitaxial layers comprising different active layers may be grown on the same wafer and, therefore, the semiconductor device may emit light of a combination of different wavelengths.

### BACKGROUND OF THE INVENTION

(1) Field of the Invention

The present invention relates to textures on substrate and on epitaxial layer and method for localizing and minimizing effects of lattice mismatch in the interface layer.

(2) Prior Art

The epitaxial layers in a semiconductor device structure should have the same lattice spacing between atoms and should match the substrate spacing as closely as possible. The lattice mismatch can be accommodated either by coherent strain or by other mechanisms, such as bending of the epitaxial layer, tilt of the lattices with respect to each other, dislocation generation at the interface, in which cases poor crystalline quality results.

To reduce effects of lattice mismatch, a single-layer or multi-layer buffer has been introduced between substrate and epitaxial layer. However there is still remaining strain in the interface of the buffer layer atop of a vastly lattice mismatched substrate. The remaining strain also causes breaking wafers during lapping and dicing processes. In practice, therefore, there is a need for a new method to minimize effects of remaining strain of lattice mismatching.

There are varieties of prior art discussing buffer layer(s), including U.S. Pat. No. 6,495,867 B1 by Chen et al. for multi-layer buffer, U.S. Pat. No. 6,233,265 B1, by Bour et al. for thick buffer layer, and U.S. Pat. No. 5,686,738 by Moustakas for single-layer buffer. The above mentioned patents are for GaN material of LED, the most commonly used substrate for GaN is sapphire (Al2O3) that is poorly matched structurally. Lattice mismatch also exists in other semiconductor devices.

Besides patents about buffer layers, there is lack of prior art that discusses localizing and minimizing effects of lattice mismatch.

### BRIEF SUMMARY OF THE INVENTION

In the present invention, (1) texturing a surface of a substrate is disclosed; (2) texturing epitaxial layer(s) is disclosed; (3) texturing substrate and epitaxial layer(s) on the same wafer multiple times is disclosed; (4) a new method for localizing and minimizing effects of lattice mismatch is disclosed.

The primary object of this invention is to provide both texturing substrate and a new method such that the effects of remaining strain between substrate and buffer layer is localized and minimized and, thus, performance of semiconductor device, yield, and throughput of production are improved.

The second object of the present invention is to provide a new method such that multiple epitaxial structures may be grown on the same wafer with minimized effects of lattice mismatch between different structures and, therefore, a semiconductor device will emit light which is a combination of different wavelengths.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIG. 1a is a cross sectional view of an epitaxial wafer with thick substrate of prior art.

FIG. 1b is a top view of the epitaxial wafer with pattern of devices.

FIG. 2a is a cross sectional view of a bended epitaxial wafer with thinned substrate of prior art.

FIG. 2b is a top view of the bended epitaxial wafer.

FIG. 3a is a cross sectional view of a substrate with texture on its top surface of a preferred embodiment of the present invention.

FIG. 3b is a top view of the textured substrate.

FIG. 4a is a cross sectional view of a textured substrate with either buffer layer or epitaxial layer grown on its top surface.

FIG. 4b is a schematic top view of the texture on the textured substrate.

FIG. 5 is a cross sectional view of a epitaxial wafer comprising buffer layer, epitaxial layer, and textured substrate.

FIG. 6a is a cross sectional view of a textured substrate with a buffer layer.

FIG. 6b is a cross sectional view of the textured substrate with a flattened buffer layer.

FIG. 6c is a cross sectional view of the textured substrate with the flattened buffer layer and an epitaxial layer grown on the top surface of the flattened buffer layer.

FIG. 7 is a cross sectional view of an epitaxial wafer with two buffer layers and two epitaxial layers grown on one side of a textured substrate.

FIG. 8 is a cross sectional view of an epitaxial wafer with two epitaxial layers grown on one side of a textured substrate.

FIG. 9 is a cross sectional view of an epitaxial wafer with one buffer layer and one epitaxial layer on each side of a textured substrate.

FIG. 10 is a cross sectional view of an epitaxial wafer with one epitaxial layer on each side of a textured substrate.

### DETAILED DESCRIPTION OF THE INVENTION

While embodiments of the present invention will be described below, those skilled in the art will recognize that other structures and methods are capable of implementing the principles of the present invention. Thus the following description is illustrative only and not limiting.

Reference is specifically made to the drawings wherein like numbers are used to designate like members throughout.

Note the followings: (1) Dimensions in all of the drawings are not to scale, (2) Epitaxial layer comprises N type and P type confinement layers and active layer, (3) substrates mentioned in the present invention may be either emit light or not emit light, and (4) “buffer layer” mentioned in the present invention stands for either one buffer layer or multiple buffer layers.

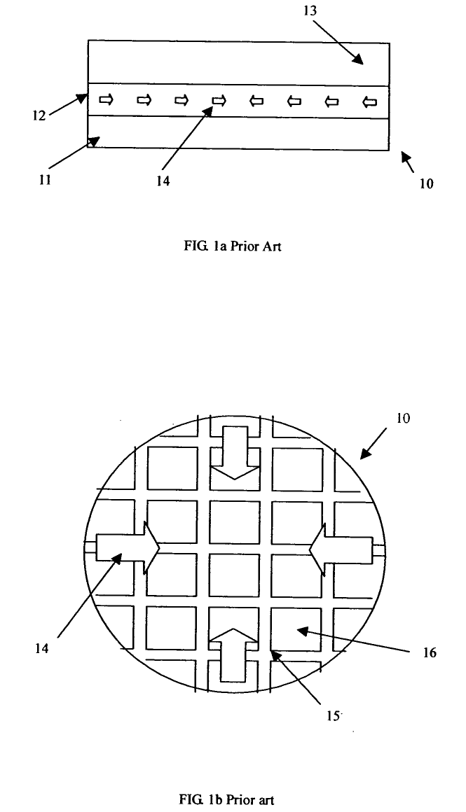

FIG. 1a is a cross sectional view of a thicker epitaxial wafer of prior art. Epitaxial wafer 10 that has gone through wafer fabrication process, comprises substrate 11, buffer layer 12 grown on the top surface of substrate 11, and epitaxial layer 13 grown on the top of buffer layer 12. Force 14 due to lattice mismatch is in the interface between buffer layer 12 and substrate 11 and parallels to the interface. Before lapping, substrate 11 is thick enough to stay flat although there is remaining strain in the interface.

FIG. 1b is a top view of epitaxial wafer 10. Device 16 is one of devices shown on the top surface of epitaxial wafer 10 and separated from other devices by street 15.

Force 14 shows that forces due to lattice mismatch are pointing inwards.

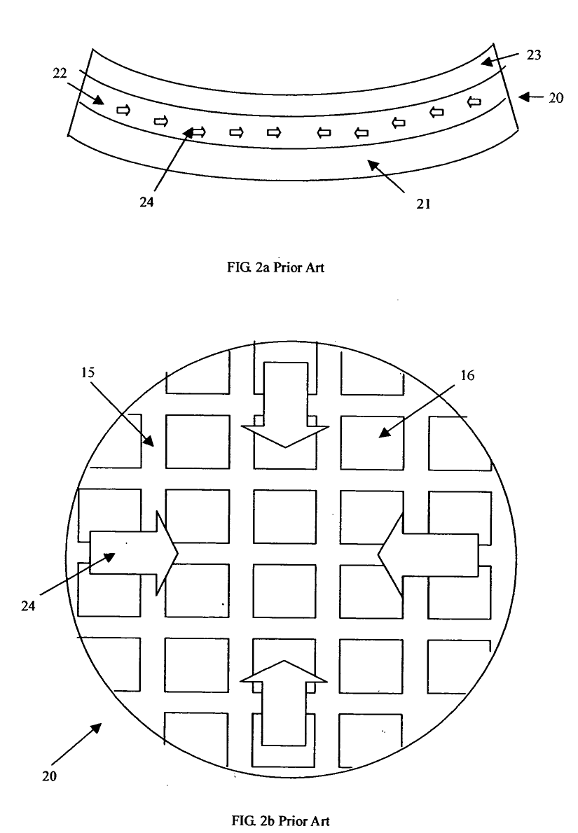

FIG. 2a is a cross sectional view of thinned epitaxial wafer 20 of prior art. Thinned epitaxial wafer 20 comprises buffer layer 22 grown on the top surface of substrate 21 and epitaxial layer 23 grown on the top surface of buffer layer 22. In wafer and die fabrication processes, it is often seen that after lapping, thinned epitaxial wafer 20 is bowled, because of the following reasons, (1) force 24 tries to pull buffer layer 22 back to its normal lattice constant, and (2) substrate 21 is thinned to certain thickness and no longer strong enough to against force 24 of strain. Both buffer layer 22 and epitaxial layer 23 are bended due to lattice mismatch.

During lapping process, it also often happens that thinned epitaxial wafer is broken to pieces, therefore, not only chips along the broken line are wasted, but also the following processes, testing, dicing and sorting, will take longer time, i.e., lower the yield and throughput.

FIG. 2b shows a top view of the thinned epitaxial wafer of prior art. Device 16 is separated by street 15. Force 24 points inward.

Note that for different buffer material grown on different substrates, thinned epitaxial wafers may bend towards to substrate side.

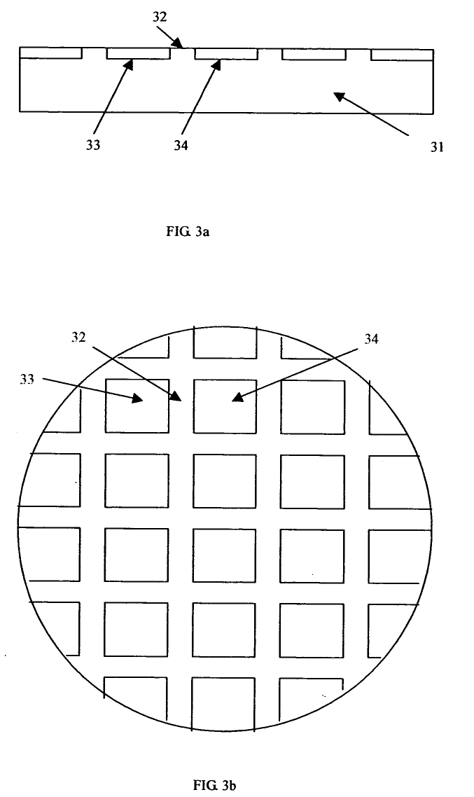

FIG. 3a is a cross sectional view of a preferred embodiment of the present invention. Texture comprising well 33 and wall 32 is patterned by etching on the top surface of substrate 31. Well 33 and well 34 are separated by wall 32. The depth of well 33 is in the range of nanometers to micrometers or thicker. The width and length of well 33 may be the same as device. The width of wall 32 is in the range of nanometers to micrometers or wider.

FIG. 3b is a top view of substrate 31 with patterns of well 33 and wall 32 on the top surface.

Note the followings: (1) the shape of well is not limited to square and may be different, such as circle; (2) The width and length of well 33 may be different from that of device, even much smaller than that of device; (3) FIG. 3b shows the pattern of etched wells and walls, not a pattern of devices.

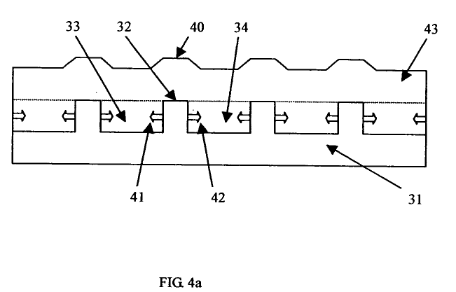

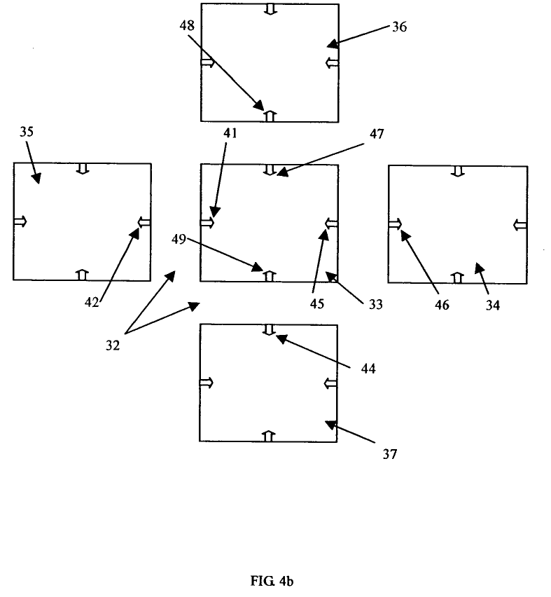

FIG. 4a is a cross sectional view of substrate 31 with texture comprising well 33, well 34, and wall 32 on its top surface.

FIG. 4a illustrates 2 different preferred embodiments as the following:

(A) Buffer layer 43 is grown on the texture of substrate 31;

(B) Epitaxial layer 43 is directly grown on the texture of substrate 31. Hereafter term buffer/epitaxial layer 43 will be used to represent those two preferred embodiments for FIG. 4a.

Bump 40 is above wall 32 and on the top surface of buffer/epitaxial layer 43. Force 41 in well 33 is in the interface between substrate 31 and buffer/epitaxial layer 43, parallels to the interface, indicates the direction of force due to lattice mismatch, and points inwards to the left. Force 42 in well 34 points inwards to the right. Therefore, the effects of force 41 and force 42 on substrate 31 are balanced. Substrate 31 stays flat even after thinned.

Note that with textured substrate, epitaxial layer may be directly grown on the top of the texture of substrate 31, since that the texture will minimize the effects of lattice mismatch.

FIG. 4b is a schematic top view of well 33 and adjacent well 34, well 35, well 36, and well 37. Those wells are separated by wall 32. In each well, forces point inwards, such as force 41, force 49, force 45, and force 47 are inside well 31 and point inwards. The effects of force 41 and force 42 on substrate are balanced, as well as force 49 and force 44, force 45 and force 46, and force 47 and force 48. Therefore, substrate stays in flat.

Walls stop the propagation of strain in the interface between buffer/epitaxial layer and substrate layer. The effects of strain are localized and, therefore, minimized.

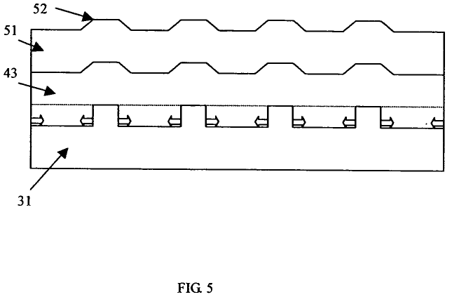

FIG. 5 is a cross sectional view of epitaxial wafer. Buffer layer 43 is grown on the texture of substrate 31. Epitaxial layer 51 is grown on buffer layer 43. There is bump 52 on the top surface of Epitaxial layer 51.

When the depth of well is in the order of nanometer or less, the effect of bump 52 is ignorable, so epitaxial layer 51 may directly grow on buffer layer 43.

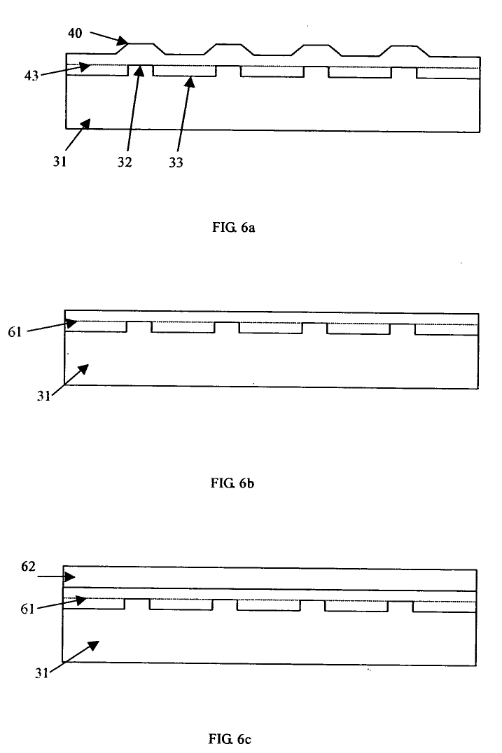

When the depth of well is in the order of micrometers, it is needed to remove bump on the top surface of buffer layer before growing other epitaxial layers. The bump may be removed by etching as shown in FIG. 6.

FIGS. 6a, 6b, and 6c show a process: (1) growing a buffer layer on the texture of substrate, (2) remove bump on the top surface of buffer layer, (3) growing other epitaxial layers on the top surface of buffer layer.

FIG. 6a shows a cross sectional view of textured substrate 31 with buffer layer 43 grown on it. Well 33 is etched on the top surface of substrate 31. Bump 40 is on the top surface of buffer layer 43.

FIG. 6b shows a cross sectional view of substrate 31. Bump 40 in FIG. 6a has been removed by etching, so buffer layer 43 of FIG. 6a became buffer layer 61 of FIG. 6b, and the top surface of buffer layer 61 is flat.

FIG. 6c shows an epitaxial wafer comprising substrate 31, buffer layer 61, and epitaxial layer 62.

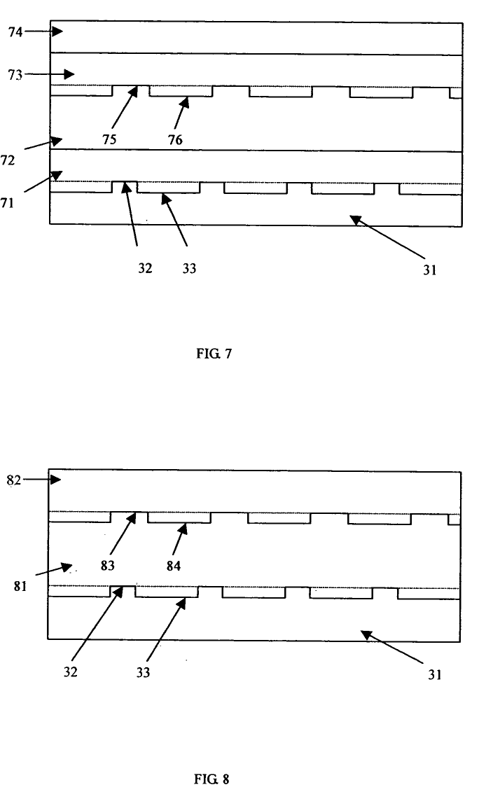

The principle of the present invention may be applied multiple times on the same wafer. This is especially important for designing a device that will emit light of a combination of different wavelengths. FIG. 7 to FIG. 10 are four of preferred embodiments of the present invention.

FIG. 7 shows a cross sectional view of epitaxial wafer. First texture comprising well 33 and wall 32 is etched on the top surface of substrate 31. First buffer layer 71 is grown on the first texture of substrate 31. First epitaxial layer 72 comprising first active layer is grown on the top surface of first buffer layer 71.

Second texture comprising well 76 and wall 75 is patterned by etching on the top surface of first epitaxial layer 72. Second buffer layer 73 is grown on the second texture of first epitaxial layer 72. Second epitaxial layer 74 comprising second active layer is grown on the top surface of second buffer layer 73. Lights of different wavelength emitted from first epitaxial layer 72 and second epitaxial layer 74 are combined and emitted out of device.

Note that bumps on the top surfaces of both first buffer layer 71 and second buffer layer 73 are not shown in FIG. 7, since either the heights of bumps are ignorable or bumps have been removed by etching before growing next epitaxial layer.

The dimensions of well 33 and wall 32 may be different from that of well 76 and wall 75.

FIG. 8 is a cross sectional view of an epitaxial wafer. There is first texture on the top surface of substrate 31, comprising well 33 and wall 32. First epitaxial layer 81 is directly grown on the top of texture. Second texture comprising well 84 and wall 83 is etched on the top surface of first epitaxial layer 81. Then second epitaxial layer 82 is grown on the top of second texture.

In this preferred embodiment, there is no buffer layer grown on the top of texture.

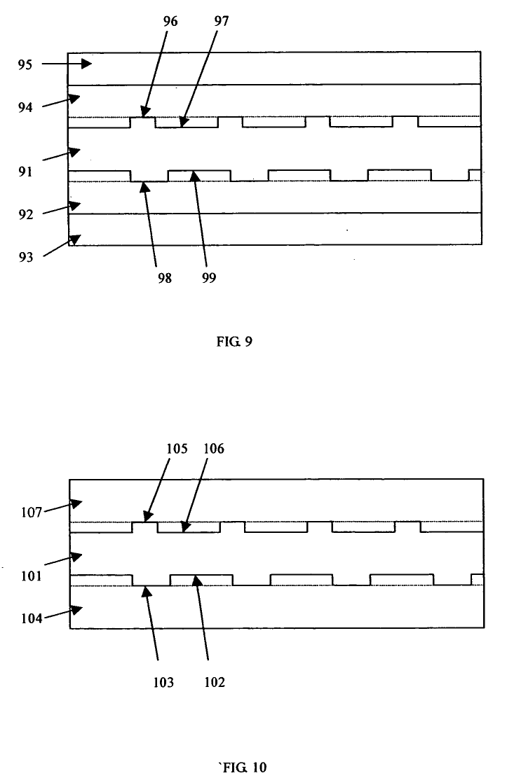

FIG. 9 shows substrate 91 with textures on both sides. Substrate 91 is transparent and thinned to required thickness. The dimensions of textures on both sides may be either the same or different depending on the materials of both substrate and buffer layers.

First texture is on one surface of substrate 91 and comprises well 97 and wall 96. First buffer layer 94 is grown on the first texture of substrate 91. First epitaxial layer 95 is grown on the top surface of first buffer layer 94.

Second texture is on the other surface of substrate 91 and comprises well 99 and wall 98. Second buffer layer 92 is grown on the second texture of substrate 91. Second epitaxial layer 93 is grown on the top surface of second buffer layer 92. The dimensions of well 97 and well 99 may be either the same or different.

Note that bumps on the top surfaces of both second buffer layer 92 and first buffer layer 94 are not shown in FIG. 9, since either the heights of bumps are ignorable or bumps have been removed by etching before growing epitaxial layers.

FIG. 10 shows substrate 101 with first texture on one surface and second texture on other surface, wherein first texture comprises well 106 and wall 105, and second texture comprises well 102 and wall 103. First epitaxial layer 107 is directly grown on the top of first texture. Second epitaxial layer 104 is directly grown on the top of second texture. Without buffer layer, the dimensions of first and second textures may be very small in order to separate the interface into small area to minimizing the effects of lattice mismatch. Substrate 101 is transparent and thinned to required thickness.

Note that bumps on the top surfaces of both second epitaxial layer 104 and first epitaxial layer 107 are not shown in FIG. 10, since either the heights of bumps are ignorable or bumps have been removed by etching before growing epitaxial layers.

Note that it is easier to use laser or dicing saw to cut textured epitaxial wafer after wafer fabrication.

Although the description above contains many specifications, these should not be construed as limiting the scope of the present invention but as merely providing illustrations of some of the presently preferred embodiments of the present invention.

Therefore the scope of the present invention should be determined by the claims and their legal equivalents, rather than by the examples given.

1. A semiconductor device, comprising:
a substrate with texture on the top surface of said substrate, and
an epitaxial layer comprising an active layer and grown on the top of said texture.

2. The semiconductor device of claim 1, further comprising buffer layer grown in between said epitaxial layer and said texture.

3. The semiconductor device of claim 1, wherein said texture comprising wells and walls.

4. The semiconductor device of claim 3, wherein the width of said walls is in a range of nanometers to micrometers.

5. The semiconductor device of claim 3, wherein the depth of said well is in a range of nanometers to micrometers.

6. The semiconductor device of claim 3, wherein said wells having a shape of rectangular.

7. The semiconductor device of claim 6, wherein the dimension of said wells is in the range of nanometers to micrometers.

8. The semiconductor device of claim 1, wherein said epitaxial layer of said semiconductor device its light.

9. A semiconductor device, comprising
a substrate with first texture on one of its two surfaces,
a first epitaxial layer comprising first active layer and grown on the top of said first texture,
a second texture etched on the top surface of said first epitaxial layer,
a second epitaxial layer comprising second active layer and grown on the top of said second texture.

10. The semiconductor device of claim 9, further comprising first buffer layer grown in between said first epitaxial layer and said first texture of said substrate, and a second buffer layer grown in between said second epitaxial layer and said second texture of said first epitaxial layer.

11. The semiconductor device of claim 9, wherein both said first texture and said second texture comprising wells and walls.

12. The semiconductor device of claim 11, wherein the width of said walls is in a range of nanometers to micrometers.

13. The semiconductor device of claim 11, wherein the depth of said wells is in a range of nanometers to micrometers.

14. The semiconductor device of claim 11, wherein said wells have the shape of said semiconductor device.

15. The semiconductor device of claim 11, wherein the dimension of said wells is in the range of nanometers to micrometers.

16. The semiconductor device of claim 9, wherein said substrate emits light.

17. A semiconductor device, comprising
a transparent substrate with first texture on one of its two surfaces and second texture on other surface,
a first epitaxial layer comprising first active layer and grown on the top of said first texture,
a second epitaxial layer comprising second active layer and grown on the top of said second texture.

18. The semiconductor device of claim 17, further comprising first buffer layer grown in between said first epitaxial layer and said first texture of said substrate, and a second buffer layer grown in between said second epitaxial layer and said second texture of said substrate.

19. The semiconductor device of claim 17, wherein both said first texture and said second texture comprising wells and walls.

20. The semiconductor device of claim 19, wherein the width of said walls is in a range of nanometers to micrometers.

21. The semiconductor device of claim 19, wherein the depth of said wells is in a range of nanometers to micrometers.

22. The semiconductor device of claim 19, wherein said wells have the shape of said semiconductor device.

23. The semiconductor device of claim 19, wherein the dimension of said wells is in the range of nanometers to micrometers.

24. The semiconductor device of claim 1, further comprises a second texture formed on the top of said epitaxial layer.

25. The semiconductor device of claim 24, further comprises a second epitaxial layer grown on the top of said second texture and comprising a second active layer.

26. The semiconductor device of claim 25, further comprising a second buffer layer grown in between said second epitaxial layer and said second texture.
